(19) United States
(12) Patent Application Publication
(10) Pub. No.: US 2012/0251310 A1
(43) Pub. Date: Oct. 4, 2012

(54) METHOD FOR PRODUCING AN ABRADABLE COATING ON A TURBOMACHINE

(75) Inventors: Wolfgang Wachter, Cincinnati, OH (US); Manuel Hertter, Muenchen (DE)

(73) Assignee: MTU Aero Engines GmbH, Muenchen (DE)

(21) Appl. No.: 13/505,028

(22) PCT Filed: Oct. 30, 2010
(86) PCT No.: PCT/DE10/01277

§ 371 Date: Jun. 14, 2012

(30) Foreign Application Priority Data
Oct. 31, 2009 (DE) 10 2009 051 554.2

(51) Int. Cl. C23C 16/50; F04D 29/40

(52) U.S. Cl. 415/200; 427/580

(57) ABSTRACT

In a method for producing an inlet coating (21) on a surface of a turbomachine (10), an electric arc (37) is produced between a first electrode (31) having a first material and a second electrode (32) having a second material. A gas stream (42) is produced through the electric arc (37) onto the surface, which entrains the first material and the second material from the electric arc (37) and deposits them on the surface to form the inlet coating (21) or a precursor layer (22) of the inlet coating (21).

The present invention relates to a method for producing an inlet coating on a turbomachine, a component of a turbomachine, and a turbomachine having an inlet coating.

### BACKGROUND

Axial compressors and gas turbines, as are used, for example, in gas turbine engines for aircraft or other mobile or stationary applications, typically include multiple stages having rotating moving blades or rotor blades and fixed guide blades or stator blades. The rotor blades are rigidly connected to a rotor and rotate therewith at high speed around an axis.

An essential feature of axial compressors and gas turbines is the pressure differences which exist between the upstream side and the downstream side of each blade ring. Any pressure loss on the outer edge of a rotor blade ring or on the inner edge of a stator blade ring reduces the efficiency.

Because of high speeds, partially high temperatures, and radial and axial deflections, which originate from vibrations and different coefficients of expansion and temperatures of the participating components, labyrinth seals or gap seals are predominantly used. For example, a sealing fin on the rotating component engages in a groove on the stationary component or vice versa.

The precise dimensions of the sealing fin and above all the groove are often not already set or provided upon the manufacturing. Rather, for example, a fin having a hard material digs into an inlet coating during a breaking-in procedure of the turbomachine and thus forms the corresponding groove therein. The inlet coating has a material which may be easily removed for this purpose.

### BRIEF SUMMARY OF THE INVENTION

Inlet coatings are typically produced, inter alia, by flame spraying and plasma spraying. However, a chemical reaction of the powdered material may occur in the hot flame. For example, during the flame spraying of nickel and graphite, the graphite may combust. This has a significant influence on the hardness of the produced layer, but it is difficult to control or avoid. Overall, in the case of flame spraying, significant variations in the thickness and other properties of the layer arise because of the process.

Precise control or monitoring of all parameters is also required in the case of plasma spraying in order to obtain a hardness of the inlet coating in a desired range. It is often necessary to admix polymer to the powder. The polyester is burned off after the coating in a separate method step at high temperature in a furnace. This produces substantial additional costs.

One object of the present invention is to provide an improved method for producing an inlet coating on a turbomachine, an improved component of a turbomachine, and an improved turbomachine.

Various specific embodiments of the present invention are based on the idea of producing an inlet coating on a turbomachine or on a component for a turbomachine by wire arc spraying. The material of the inlet coating is removed from the electrodes using an electric arc between two electrodes and propelled by a gas stream onto the surface to be coated.

One advantage of wire arc spraying is its comparatively low costs, in particular for this application. Through the selection of the gas, which does not have to contain oxygen to maintain a flame, oxidation or another undesirable chemical reaction of the material forming the inlet coating may be prevented while it is still in the gas stream or even after the deposition. Furthermore, a mixture of multiple materials may readily be produced in a predetermined ratio, in that electrodes having these materials in the desired ratio are used.

The production of an inlet coating using wire arc spraying allows a significantly better reproducible result in comparison to several conventional methods, in particular significantly better reproducible properties of the inlet coating. For example, the variation of the powder grain fraction and the resulting variation of the hardness and other properties of the inlet coating may be substantially reduced.

Another advantage of the production of an inlet coating using wire arc spraying is that the result, in particular the finished inlet coating, is provided significantly more rapidly than several other methods. This may in turn simplify the quality control and the regulation of the process.

In particular, a material soluble in water or another predetermined solvent and a material insoluble in this predetermined solvent are applied simultaneously by wire arc spraying. In the present case, a material is also designated as soluble in a solvent in particular if it reacts with water or another predetermined solvent to form a compound soluble in the solvent. When the soluble material is subsequently dissolved away, pores remain in the insoluble material, because of which the inlet coating is easily removable.

In a method for producing an inlet coating on a surface of a turbomachine, an electric arc is produced between a first electrode having a first material and a second electrode having a second material. A gas stream is produced through the electric arc toward the surface to be coated, which entrains the first material and the second material from the electric arc and deposits them on the surface, in order to form the inlet coating or a precursor layer of the inlet coating.

Each of the two electrodes may contain one of the two materials or both materials. For example, the first electrode only has a first material and the second electrode only has a second material; or each of the two electrodes has both materials.

In particular, the first material may be insoluble in a predetermined solvent—for example, water or alcohol—while the second material is soluble in the predetermined solvent. This also includes the solubilities of the first material and the second material differing significantly, for example, by a factor of 10, 20, 50, or 100. The layer produced as described is a precursor layer of the inlet coating in this case. Upon action of the solvent on the precursor layer, the second material is dissolved away from the precursor layer to obtain a porous structure, which only still has or essentially only still has the first material and forms the inlet coating.

The first material includes, for example, nickel or a nickel alloy or another water-insoluble metal alloy. The second material includes, for example, Al₂OSn or another water-soluble metal alloy, the solvent being water or an acid or a base. Both the first material and also the second material may also include additives, for example, graphite, polyester, bentonite, boron nitride, or another ceramic, mineral, or organic material.

The present invention also includes a component of a turbomachine and a turbomachine having an inlet coating produced as described above.

### BRIEF DESCRIPTION OF THE FIGURES

Specific embodiments are explained in greater detail hereafter on the basis of the appended figures.

FIG. 1 shows a schematic view of a gas turbine engine;

FIG. 2 shows a schematic view of a device for producing an inlet coating on a gas turbine engine;

FIG. 3 shows a schematic flow chart of a method for producing an inlet coating.

### DETAILED DESCRIPTION

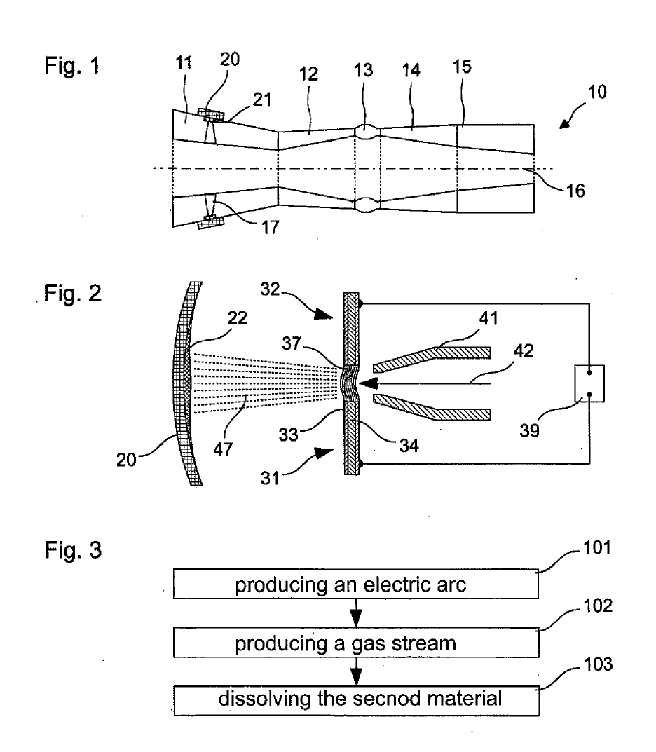

FIG. 1 shows a schematic view of a gas turbine engine for mobile or stationary applications as an example of a turbomachine. Gas turbine engine 10 includes a low-pressure compressor 11, a high-pressure compressor 12, a combustion chamber 13, a high-pressure turbine 14, and a low-pressure turbine 15. Gas turbine engine 10 has multiple stator blade rings and multiple rotor blade rings. Only one rotor blade ring 17 thereof is shown in FIG. 1. A component 20 having an inlet coating 21 is arranged on the outer circumference of rotor blade ring 17, into which a sealing fin on the outer circumference of rotor blade ring 17 may dig to form a gap seal or a labyrinth seal. The illustration of rotor blade ring 17, component 20, and inlet coating 21 in the area of low-pressure compressor 11 is exemplary. An arrangement of the inlet coating according to the present invention in the area of high-pressure compressor 12 or in another area of gas turbine engine 10 is also possible.

FIG. 2 shows a schematic view of a device for producing a precursor layer 22 of an inlet coating 21 on a component 20 of a gas turbine engine. The device includes a first electrode 31 and a second electrode 32. Each of the two electrodes 31, 32 includes a sheath 33 and a filler 34. For the purpose of a comprehensible illustration, these are only provided with reference numerals on first electrode 31.

In the illustrated example, sheath 33 is tubular and has a circular, square, or rectangular cross section and a central cavity. Filler 34 is situated in the central cavity of sheath 33. Sheath 33 has a first material, filler 34 has a second material. At least one of the two materials has an electrical conductivity.

Alternatively, the two electrodes 31, 32 are each formed from a wire, first electrode 31 having the first material and second electrode 32 having the second material. Furthermore, one of the two electrodes 31, 32 may have two materials as described above and the other electrode may only have one material.

To produce an electric arc 37 between the two electrodes 31, 32, each of the two electrodes 31, 32 is connected to one pole of an electrical power source 39. Electrical power source 39 is, for example, a DC voltage or AC voltage or direct current or an alternating current source.

The device for producing a precursor layer 22 of an inlet coating on a turbomachine also includes a nozzle 41, which is directed at the space between electrodes 31, 32. An apparatus is designed to produce a gas stream 42, which is directed from nozzle 41 onto the space between electrodes 31, 32.

To produce a precursor layer 22 of an inlet coating 21 on component 20, an electric arc 37 is produced between electrodes 31, 32 using electrical power source 39. Electrodes 31, 32 are consumed by electric arc 37. In particular, material is melted or vaporized by electric arc 37 at the ends of electrodes 31, 32. Electric arc 37 contains material of electrodes 31, 32 in partially ionized atomic or molecular form or in the form of partially ionized atomic clusters, particles, or droplets. This material is partially entrained by the gas stream exiting from nozzle 41. A coating stream made of material of electrodes 31, 32 arises. The gas stream thus propels the material of electrodes 31, 32 removed by electric arc 37 onto component 20 or the substrate to be coated. Coating stream 47 strikes component 20 and produces precursor layer 22 of an inlet coating thereon. If oxidation of the materials of electrodes 31, 32 in electric arc 37 in coating stream 47 and/or in inlet coating 21 is to be avoided, gas stream 42 may be oxygen-poor or oxygen-free, inert, or reducing.

The composition of precursor layer 22 on component 20 is determined by the composition of electrodes 31, 32. Both electrodes 31, 32 may have identical or different compositions of identical or different materials. Instead of the configuration of each electrode 31, 32 from a sheath 33 and a filler 34, as shown in FIG. 2, one of the two electrodes 31, 32 or both electrodes 31, 32 may have a homogeneous configuration.

For example, first electrode 31 in the inhomogeneous configuration shown in FIG. 2 or in a homogeneous configuration has nickel or a nickel alloy or another water-insoluble metal alloy. Furthermore, first electrode 31 may have a pure or metal-sheathed additive, for example, graphite, polyester, bentonite, boron nitride, or another ceramic, mineral, or organic material. The mechanical properties of the additive are selected in particular in such a way that it may be easily abraded or removed. Second electrode 32 has, for example, Al₂OSn or another alloy having a higher solubility in water, acid, base, or alcohol. Alternatively, each of the two electrodes 31, 32 has both a material insoluble in a predetermined solvent and also a material soluble in the predetermined solvent.

In the arrangement shown in FIG. 2, precursor layer 22 is created having the inhomogeneous thickness shown. Precursor layer 22 may be produced having a homogeneous thickness or having a desired thickness profile through a lateral movement of the component and the device relative to one another.

After the production of precursor layer 22, the soluble material is dissolved away from the precursor layer by an action of the predetermined solvent. A porous structure made of the insoluble material remains, which forms the inlet coating.

FIG. 3 shows a schematic flow chart of a method for producing an inlet coating on a turbomachine. Although this method may also be carried out on turbomachines and using devices which differ from those illustrated above on the basis of FIGS. 1 and 2, reference numerals from FIGS. 1 and 2 are used hereafter as examples to make understanding easier.

In a first step 101, an electric arc 37 is produced between a first electrode 31 having a first material and a second electrode 32 having a second material. In a second step 102, a gas stream 42 is produced and directed by a nozzle 41 onto electric arc 37. The gas stream entrains the first material and the second material from electric arc 37 and deposits them on the surface to be coated to form a precursor layer 22. In a third step 103, the second material, which is soluble in a predetermined solvent, is dissolved away from precursor layer 22 by the action of the predetermined solvent thereon. A porous structure of the first material remains, which forms inlet coating 21.

Alternatively, inlet coating 21 is produced directly by depositing the material of electrodes 31, 32 onto the surface to be coated, third step 103 being omitted.

What is claimed is:

1-8. (canceled)

9. A method for producing an inlet coating on a surface of a turbomachine, comprising the following steps:
producing an electric arc between a first electrode having a first material and a second electrode having a second material;
producing a gas stream through the electric arc onto the surface, the gas stream entraining the first material and the second material from the electric arc and depositing the first and second material on the surface to form the inlet coating or a precursor layer of the inlet coating.

10. The method as recited in claim 9 wherein both the first and second electrodes contain the first material and the second material.

11. The method as recited in claim 9 wherein the first material is insoluble in a predetermined solvent and the second material is soluble in the predetermined solvent.

12. The method as recited in claim 11 further comprising dissolving the second material away from the precursor layer of the inlet coating with aid of the predetermined solvent, to obtain a porous structure of the first material, the first material forming the inlet coating.

13. The method as recited in claim 11 wherein the second material includes a water-soluble metal alloy, and the predetermined solvent has water or an acid or a base.

14. The method as recited in claim 13 wherein the metal alloy is Al₂OSn.

15. The method as recited in claim 1 wherein the first material includes a ceramic, mineral, or organic material.

16. The method as recited in claim 15 wherein the first material includes at least one of graphite, polyester, bentonite, and boron nitride.

17. A component of a turbomachine comprising:
an inlet coating produced as recited in claim 9.

18. A turbomachine comprising:
an inlet coating produced as recited in claim 9.
